(19) United States
(12) Patent Application Publication
(10) Pub. No.: US 2013/0249034 A1
(43) Pub. Date: Sep. 26, 2013

(54) Optical Device, Wafer-Scale Package for One Such Optical Device and Corresponding Method

(71) Applicant: Luc Andre, Grenoble (FR)

(72) Inventor: Luc Andre, Grenoble (FR)

(73) Assignee: Commissariat A L'Energie Atomique et aux Energies Alternatives, Paris (FR)

(21) Appl. No.: 13/812,405

(22) PCT Filed: Jul. 26, 2011
(86) PCT No.: PCT/IB11/53328

§ 371 Date: Jun. 8, 2013

(30) Foreign Application Priority Data
Jul. 26, 2010 (FR) 1056124

(51) Int. Cl. G02B 3/00; G02B 1/10; G02B 1/11; G02B 13/14; H01L 27/146; G02B 3/04

(52) U.S. Cl. CPC G02B 3/00; H01L 27/146; G02B 3/04; G02B 1/11; G02B 13/14; G02B 1/10
USPC 257/432; 359/642; 438/68; 359/664; 359/708; 359/601; 359/356; 427/508

(57) ABSTRACT

The invention relates to an optical device produced by cutting a wafer-scale package comprising at least one optical module formed from a substrate (1) pierced with a plurality of through-holes (2) and optical elements disposed in the holes. According to the invention, at least one of the holes receives two lenses (3, 4) made from at least one polymer material transparent in the 400 nm-700 nm range, each of the lenses being defined by an external diopter and an internal diopter. The invention is characterised in that a space is formed between the internal diopters of two lenses and in that the substrate contains no polymer material between two adjacent through-holes.

The invention relates to the field of optical devices such as camera devices and, more particularly, wafer-level packages for such devices.

These devices are notably designed for mobile telephones or for PDAs (Personal Digit Assistant).

Thus, the document U.S. Pat. No. 7,564,496 describes a camera device comprising an element for acquiring images, for example a CMOS imaging system and a stack of optical assemblies, spacers being provided between the optical assemblies and between the image capture element and the stack of optical assemblies.

Each optical assembly comprises a substrate and lenses which can be formed on the substrate or in through-holes of the substrate.

Furthermore, the substrate can be made of an optically transparent material such as glass or quartz. It may also be made of an opaque material so as to avoid reflections of stray light within the camera device. This embodiment obviates the need for the optical encasement around the stack of optical modules.

Other documents describe optical modules comprising a substrate with through-holes, within which a lens made from photoresist is formed.

Thus, the document JP-2009300596 describes a lens made of resin which completely fills the hole formed in the substrate, the edges of the lens being supported on the side walls of the hole. This lens is bounded, on either side of the substrate, by two air-photoresist interfaces, where each of them may be spherical or aspherical.

Similarly, the document JP-2009251366 describes a substrate comprising a lens in each through-hole formed in the substrate, the edges of the lens being supported by the side walls of the hole.

Here again, each lens is bounded, on either side of the substrate, by two air-photoresist interfaces which can be spherical or aspherical.

The optical modules described in these documents require the use of a large quantity of resin, which has negative consequences on the temperature behavior of the optical module.

Generally speaking, increases in temperature can occur either during the fabrication of the optical device, or during the use of the latter when it is integrated, for example, into a mobile telephone.

During the fabrication of the optical device, the “reflow” step or metal connection by thermal welding is a particularly critical step. This step consists in heating to a few hundred degrees and for a few minutes the metal balls situated under the CMOS sensor in such a manner as to establish a contact between this sensor and the addressing circuit situated underneath. This step will of course heat not only these balls, but also all of the elements sitting above the sensor, and in particular the optical modules associated with the sensor.

Other significant increases in temperature may occur during the assembly of the optical modules and of the CMOS sensor.

Furthermore, during the use of the mobile telephone, the user may leave it in his car for several hours in the sun. This is a fairly severe case which can correspond to a temperature of 80° C. for several hours.

Furthermore, when the device gets hot, the materials will tend to expand. The increase in volume of these materials depends on their thermal expansion coefficient (TEC). If the thermal expansion coefficients are close, then the materials expand by the same amount. The rise in temperature does not create any mechanical stress. Conversely, if the thermal expansion coefficients are very different, the materials do not expand in the same way. An increase in temperature then has the effect of creating mechanical stresses in the assembly.

These mechanical stresses increase with the amount of photoresist present in the optical modules.

They lead to a deformation by torsion of the substrates composing the stack. This deformation has two effects. On the one hand, it can cause cracking or delamination of the stack. On the other hand, it leads to non-compliance with the mechanical dimensions of the optical modules, in other words to a deterioration in the resulting optical quality. Thus, using materials with different thermal expansion coefficients in the optical modules leads to a reduction in the mechanical performance and/or to a reduction in the quality of the image.

Furthermore, these documents all describe optical modules comprising a single lens (two non-planar optical interfaces) per through-hole of the substrate and hence only two air-photoresist or optical interfaces.

Thus, the fabrication of an optical device, notably an imaging optical device, will require the stacking of a large number of optical modules in order to obtain an acceptable image quality. Indeed, the improvement of the quality of the images requires the number of lenses in the path of the light to be multiplied, on top of the CMOS sensor, and lenses to be designed with more and more precise dimensions which will lead to high costs.

Furthermore, it is not even certain that such a stacking is possible with any type of substrate.

Indeed, the current technology uses substrates for the optical modules whose thermal expansion coefficient is very different from that of the silicon used for the CMOS sensor.

The difference between the thermal expansion coefficients leads to differences in expansion which cause stack deformations in the form of cracking or delaminations. They also lead to non-compliance with the mechanical dimensions. The use of materials with different thermal expansion coefficients is therefore incompatible with the improvement in the optical quality of imaging devices.

The number of substrates stacked in order to form an optical device will therefore need to be limited.

When silicon substrates are used, the thermal expansion coefficient of the various substrates will be identical. Nevertheless, two problems remain.

On the one hand, one lens per hole is formed. Therefore, as many substrates as lenses are needed in order to form the optical system. However, the more the number of substrates increases, the more difficult the compliance with the mechanical and optical dimensions, and hence the final image quality is difficult to obtain.

On the other hand, as underlined previously, the filling of the hole by resin has the effect of increasing the ratio between the amount of resin used and the amount of substrate. The higher this ratio, the more the optical module will have the tendency to be deformed.

The aim of the invention is to overcome these drawbacks and, for this purpose, provides an optical module formed from a substrate with a plurality of through-holes and optical elements disposed in the holes, characterized in that, in at least one hole, two lenses are disposed made of at least one polymer material that is transparent in the range 400 nm-700 nm, each of the lenses being defined by an external optical interface turned toward the outside of the through-hole and an internal optical interface turned toward the inside of the through-hole, characterized in that a gap is arranged between the internal optical interfaces of the two lenses and in that the substrate is devoid of any polymer material between two adjacent through-holes.

The presence of four air-photoresist interfaces, or of four optical interfaces, allows the number of substrates needed to form an optical device to be reduced, using a wafer-level package comprising an optical module according to the invention. This will be about half the number as with the substrates described in the documents U.S. Pat. No. 7,564,496, JP-2009300596 or JP-2009251366, which only comprise one lens by through-hole.

Thus, for a given number of lenses in an optical device, the number of substrates is smaller. As a consequence, the risks of mechanical stress are reduced and the image quality of the optical device improves.

Moreover, the absence of polymer material on the substrate between two adjacent lenses makes it possible to avoid diffusion problems.

The external optical interface can have a spherical or, alternatively, an aspherical shape in order to improve the optical quality by correcting for aberrations, in particular chromatic or geometric aberrations.

Furthermore, the internal optical interface has a plane, spherical or aspherical shape.

In one particular embodiment, the two lenses disposed in the same through-hole have different indices and Abbe values, so as to reduce the chromatism of the optical device obtained using the package according to the invention.

In another particular embodiment, the external optical interface of at least one of the two lenses disposed within the same through-hole is covered by another optical interface.

This optical interface can, for example, be aspherical, so as to correct for aberrations, in particular chromatic aberrations.

It may also be made of a material with a different index to that of the material forming the lens, so as for example to reduce the chromatism of the optical device formed using a package comprising an optical module according to the invention.

In another particular embodiment of the optical module according to the invention, in at least one through-hole comprising two lenses, the gap included between the two internal optical interfaces of the two lenses is filled with a material that is transparent in the range 400 nm-700 nm.

The index and the Abbe value of this material situated between the two internal optical interfaces can be different from those of at least one of the two lenses, in order to here again reduce the chromatic or geometric aberrations of an optical device incorporating the optical module according to the invention.

Similarly, the external optical interface of at least one of the two lenses disposed within the same through-hole may be covered with an anti-reflective and/or anti-infrared coating.

The invention also relates to a wafer-level package comprising at least one optical module according to the invention and a substrate comprising a plurality of imaging systems.

It also comprises spacers for separating the optical modules from one another or else the optical module(s) from the imaging system.

Preferably, the substrate of said at least one optical module is made of an opaque material. This thus obviates the need for the optical encasement around the stack of optical modules in the final optical device.

In this case, the material chosen is preferably silicon, in other words the same material as the imaging system. It could also be a material of the liquid crystal polymer type incorporating glass or carbon fibers or of the polysulfone type including carbon fibers. The percentage of glass or carbon fibers is in the range between 10 and 35% depending on the degree of opacity and the thermal behavior sought.

This offers two advantages. First of all, the substrates made of silicon, or one of the preceding plastic materials, avoid the penetration of stray light which could otherwise reach the imaging system and interfere with its operation. In addition, the package is then formed from a stack of substrates made of the same material or of materials having the same behavior when heated, whether this be the material composing the optical modules or the imaging system. For this reason, each substrate gets deformed in an identical fashion, which improves the behavior of the package when the temperature increases.

Advantageously, the package comprises electrical vias for the electronic addressing which passes through the substrates made of silicon or plastic material.

The invention also relates to an optical device comprising a part of a wafer-level package according to the invention, divided up along planes running in an axial direction.

The invention also relates to a method for the fabrication of an optical module according to the invention, consisting in carrying out the following steps:
(a) form a plurality of through-holes in a substrate,
(b) deposit, onto both sides of at least one through-hole, a drop of a thermally- or UV-hardening polymer, which is transparent in the range 400 nm-700 nm, in such a way that a gap is arranged, within said at least one hole, between two drops of polymer, and that the substrate is devoid of any polymer between two adjacent through-holes, and
(c) harden said polymer by exposure to heat or to UV.

Advantageously, this method consists, between the steps (b) and (c), in shaping said drop of polymer by molding.

This molding step, carried out notably by thermal imprint, allows other profiles than spherical profiles to be obtained.

In one particular embodiment, the method comprises, after the step (c), a step (d) consisting in depositing, onto at least one of the two lenses formed in a through-hole, another drop of polymer that will coat the lens previously formed and a step (e) consisting in hardening said drop of polymer by heat or by UV.

This step (e) could be followed by a step (f) for the shaping of this other drop of polymer by molding.

Here again, this allows an aspherical optical interface to be formed on the lens previously formed for correcting aberrations, in particular chromatic aberrations.

The indices and Abbe values of the various materials used to form the lenses and/or the additional optical interfaces can be different in order to reduce the chromatism.

According to another particular embodiment of the method according to the invention, prior to the step (b), the method consists in filling at least partially said through-hole with a thermally- or UV-hardening material.

The invention also relates to a method for fabricating a wafer-level package consisting in fabricating several optical modules according to the invention and in stacking them along an axial direction with a substrate comprising a plurality of imaging systems.

Preferably, the method also consists in forming, during the step (a), additional holes through all the substrates, these holes being aligned axially, the method subsequently consisting in filling these holes with a conductive polymer, then in hardening this polymer, in such a manner as to form electrical vias for the electronic addressing.

The invention lastly relates to a method for fabricating an optical device, notably a camera device, consisting in implementing the method according to the invention for the fabrication of a wafer-level package and a complementary step for cutting it up into die along planes running in an axial direction, so as to separate the package into individual optical devices.

The invention will be better understood and other aims, advantages and features of the latter will become more clearly apparent upon reading the description that follows and which is presented with regard to the appended drawings, in which:

FIG. 1 is a transverse cross-sectional view of a first example of an optical module of a wafer-level package according to the invention,

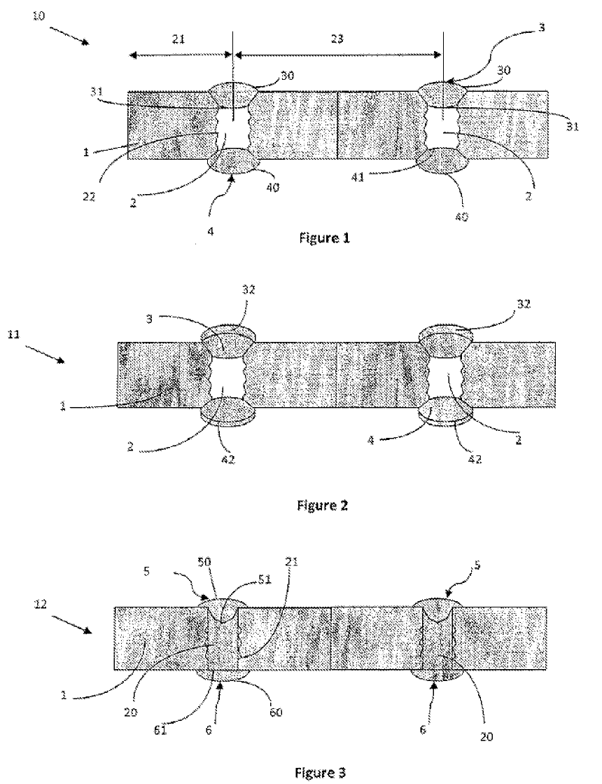

FIG. 2 is a transverse cross-sectional view of a second example of an optical module of a package according to the invention,

FIG. 3 is a transverse cross-sectional view of a third example of an optical module of a package according to the invention,

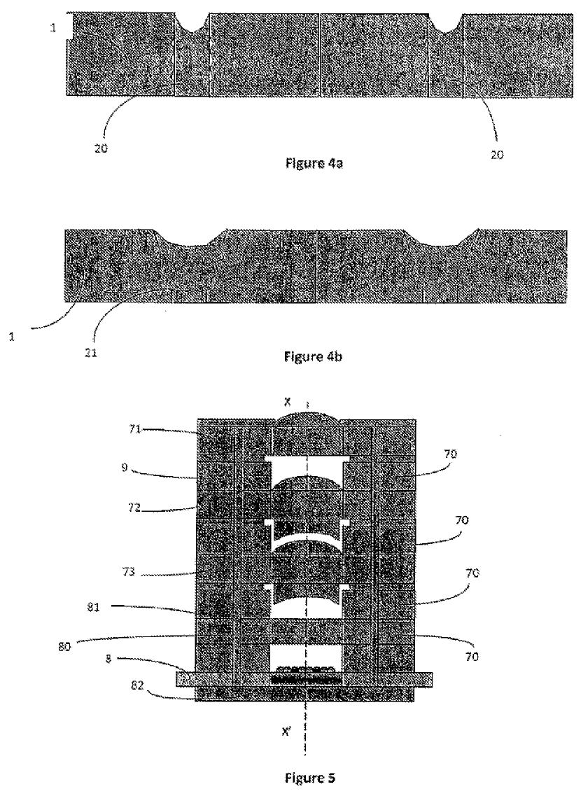

FIGS. 4a and 4b are transverse cross-sectional views showing an intermediate fabrication step, on the one hand, for the optical module illustrated in FIG. 3 and, on the other hand, for a variant of this optical module,

FIG. 5 is a transverse cross-sectional view, along a dicing plane, of an optical device according to the invention.

The common elements in the various figures will be denoted by the same references.

FIG. 1 illustrates an optical module 10 comprising a substrate 1 in which, in this example, two through-holes 2 have been made.

This substrate will preferably be made of silicon or of a plastic material of the polysulfone or liquid crystal polymer type, loaded with carbon or glass fibers.

The thickness of the substrate will be in the range between around 100 μm and a few millimeters, for example around 725 μm.

When the substrate is made of silicon, the through-holes will be formed by deep etching, for example by a technique of the DRIE (Deep Reactive Ion Etching) type, which is currently used for the formation of electrical vias through silicon substrates.

When the substrate is made of a different substance, other methods will be used. Thus, when the substrate is made of a molded plastic material, the through-holes are preferably obtained by molding.

Thus, the substrate can also be made of opaque materials that may be etched or molded. These can be metals such as tungsten, iron, copper, molybdenum or aluminum or else polymer materials such as PDMS (polydimethylsiloxane) or polymides.

The use of silicon is advantageous because it avoids the stresses linked to any potential difference between the thermal expansion coefficient of the substrate of the optical modules and that of the imaging system.

It goes without saying that, in general, a number of holes much higher than two is formed in a substrate. Thus, over a thousand through-holes are formed in a substrate with a diameter of 200 millimeters.

The diameter of the through-holes will be in the range between around 100 μm and a few millimeters, for example 700 μm.

Furthermore, the pitch 23 between two adjacent holes is a function of the diameter of the holes and of the distance 21 between the edge of the hole and the edge of the substrate, after singulation. This pitch is generally in the range between around 500 μm and a few millimeters, typically 5 mm.

This method generally leads to the formation of irregularities on the side walls 22 of the through-holes. These irregularities can be advantageously used in the framework of the fabrication method according to the invention, as will be explained later on.

At each end of at least one through-hole 2, lenses 3, 4 are formed each bounded by an external optical interface 30, 40 and an internal optical interface 31, 41.

In the example illustrated in FIG. 1, each hole 2 comprises two lenses but the invention is not limited to this embodiment. Thus, certain holes of the substrate could only comprise a single lens.

In addition, in the example illustrated in FIG. 1, the external optical interface 30, 40 of each lens is slightly protruding with respect to the substrate 1. The invention is not however limited to this embodiment and the external optical interface could be situated inside the hole. The internal optical interfaces 31, 41 are disposed facing each other within the hole 2, a gap remaining free between the two internal optical interfaces.

Each of these lenses is obtained by the deposition, on one side of the through-hole, of a drop of a polymer hardened by heat, for example a polycarbonate, or by UV. This material is of course transparent over the visible range 400 nm-700 nm.

Moreover, the deposition is carried out in such a way as to arrange a gap between the two drops of polymer which will then form the lenses.

The deposition of the polymer is moreover performed only in the through-holes. Thus, the lenses are not obtained on the basis of a layer of material deposited for example by centrifugal coating (or spin-coating to use the term of the art). Thus, in an optical module according to the invention, no constituent material is present between the external optical interfaces of two adjacent lenses or between two adjacent holes, this making it possible to avoid diffusion problems. The substrate is therefore free of any polymer material between these external optical interfaces. On the contrary, when lenses are obtained on the basis of a layer of polymer material deposited on the substrate, this material remains present between the external optical interfaces of two adjacent lenses, unless a step of etching is specifically envisaged.

The external optical interface 30, 40 of each lens has a substantially spherical shape. It is observed that the shape obtained can be controlled with an error of the order of 50 nm with respect to a perfect sphere.

The polymer is subsequently hardened by heating or by UV exposure.

The height of the lens, taken in the direction of the through-hole, is generally in the range between 10 and 400 μm.

In order to ensure a good adherence of each of the lenses within the substrate 1, the contact surface area between the polymer composing the lenses and the substrate should be large. It must typically be at least equal to the opening in the substrate. The latter is determined during the design of the imaging system. It depends on the amount of light that has to reach the sensor, on the position of the lens with respect to the sensor, on its function (field lens, aperture lens, etc.) and on the shape that the optical interface needs to have.

The polymer materials used to form the lenses 3 and 4 can have a different index. They can have an Abbe value or constringence, in other words a variation of the index with the wavelength over the range 400 nm-700 nm, which is also different.

The polymer materials typically used are PMMA (polymethylmethacrylate) or PC (polycarbonate).

For PMMA, the index is n=1.491 and the Abbe value is c=57.44.

For PC, the index is n=1.585470 and the Abbe value is c=29.909185.

Polyurethane polymers may also be mentioned whose index is n=1.64 and whose Abbe value is c=30.

The correction for the chromatism is done by the use of two materials with different properties. The first will have a low dispersion (low Abbe value), the second will be very dispersive. The use of two materials with different indices allows the chromatism to be corrected.

Furthermore, prior to the polymerization, a mold can be arranged in order to shape the drops of polymer.

This mold is generally common to the whole substrate and it is held in place during the whole period of the polymerization. The use of such a mold allows aspheric external optical interfaces to be formed so as to correct certain chromatic or geometric aberrations.

The profile of the mold is, generally speaking, defined as a function of the distance from the optical axis by an equation whose parameters are the radius of curvature, the conicity and the aspherization coefficients.

Depending on the profile chosen, an aperture lens (high conicity, low aspherization) or a field lens (low conicity, high aspherization) may for example be formed.

Furthermore, the internal optical interfaces 31, 41 can be plane or spherical. This shape is determinant in the optical quality of the final imaging system.

Generally speaking, the shape of the internal optical interface largely depends of the shape of the mold used, on the form of the substrate to be traversed and on the amount of material used to form the lens.

Thus, for a “mold/substrate to be traversed” pair having a given volume for receiving the resin if the resin volume is equal to the reception volume, the internal optical interface is then plane (or of very large radius of curvature). If the volume of resin is much greater than the reception volume, the internal optical interface is then curved (or of very small radius of curvature).

Other parameters come into play in the formation of these internal optical interfaces, notably: the wetability of the polymer, the conservation of the volume, the size and the shape of the opening in the substrate in question (made of silicon or plastic).

Finally, the external optical interfaces 30, 31 may be coated with an anti-reflective and/or anti-infrared coating.

In the case of an anti-reflective coating, this can be formed from a bilayer SiO2/TiO2 stack or a 4-layer SiO2/TiO2/SiO2/TiO2 stack, the thickness of each layer being a few tens of nanometers.

The deposition of each of these layers may be carried out by MOCVD (Metal-Organic Chemical Vapor Deposition) or CVD (Chemical Vapor Deposition), depending on the nature of the layer in question.

In this embodiment, the amount of resin used is considerably reduced with respect to that required in the prior art. Thus, the risks of mechanical stresses associated with the use of materials having different thermal expansion coefficients are also reduced.

FIG. 2 illustrates an optical module 11, similar to that described with reference to FIG. 1, comprising two lenses 3, 4 in each through-hole 2 of the substrate 1.

In the embodiment illustrated in FIG. 2, another optical interface 32, 42 is present on the external optical interface 30, 40 of each lens.

This other optical interface is obtained by the deposition, onto the external optical interface 30, 40, of a drop of polymer that will coat the lens previously formed.

This polymer is also transparent over the visible range 400 nm-700 nm and it may be hardened by heat or by UV.

As previously explained with regard to FIG. 1, a mold can be used to shape the drops of polymer in order to obtain an optical interface 32, 42 that is not necessarily spherical.

Furthermore, the materials used to form the optical interfaces 32, 42 can have a different index from the material used to form the lenses 3, 4, so as to reduce, or even eliminate, the chromatism of the optical device using this optical module. Thus, as previously explained, the material used for the lens 3 could be a low-dispersion material, whereas that used for the optical interface 32 will be very dispersive.

FIG. 3 illustrates yet another embodiment, in which the through-hole is filled with a polymer material 20, prior to the formation of the lens or lenses 3 and 4, on one side of the through-hole 2. Thus, the gap arranged between the internal optical interfaces in lenses 3 and 4 is here filled by the polymer material.

This filling polymer is necessary for holes 2 whose diameter is larger than 1.5 mm. It then enables the mechanical strength of the lenses which will subsequently be formed by deposition of a drop of polymer to be ensured.

It may furthermore be optically useful whatever the diameter of the hole.

The materials used are also polymer materials polymerizable by UV or by thermal hardening. The hardening temperature varies depending on the polymer chosen. It is generally situated between 80° C. and several hundred degrees, typically 300° C.

The chosen material exhibits good optical properties, in other words providing a transmission higher than 90% over the visible range 400 nm-700 nm, with a well-defined index and Abbe value.

The chosen material is, preferably, more flexible than the substrate 2, once hardened, in order to allow a good contact on the interface with the substrate and to thus conserve a high cohesion with the substrate, in particular when the temperature rises.

By way of example, this polymer material could be a hybrid resin or an acrylate sol gel material, a PDMS (Polydimethylsiloxane), a saturated polyester resin, an epoxide, polymide or phenolic resin, or even a vulcanized rubber.

If the substrate 2 is made of silicon, the polymer material will preferably have a thermal expansion coefficient close to that of silicon, in other words around 3.10⁻⁶/C.° at 20° C. Thus, the risk of dissociation between the substrate 2 and the polymer plug 20 will be reduced when the temperature rises.

For example, polymides possess this property.

The same is true for a liquid crystal polymer, polysulfone or polyethersulfone loaded with 30% of carbon fibers.

FIG. 3 shows that gaps 21 are left free between the plug 20 and the substrate 2, along the walls of the through-holes. They may notably correspond to the irregularities present on the side wall of the through-holes.

This embodiment is advantageous when the thermal expansion coefficients of the plug and of the substrate are different.

Indeed, in this case, when the temperature rises, the volumes occupied by each material will vary differently. Including a small gap between these materials offers the possibility for each of them to expand differently, without risk of cracking, breaking or of high mechanical stress.

Preferably, the polymer material exhibits good rheological characteristics so as to limit the risk of formation of bubbles inside of the plug 20.

Furthermore, the viscosity of the material must be sufficiently low for the material to closely match the shapes of the through-hole and sufficiently high so that the material does not run out of the through-hole, before the polymerization. Thus, the viscosity of the material will preferably be in the range between 10 000 cp and 100 cp.

If the substrate wets correctly, a resin with low viscosity will be chosen. Conversely, if the substrate wetting is limited, a resin with high viscosity will then be chosen.

The filling of the through-hole with the polymer material may for example be effected by using an inkjet technique or by serigraphy.

In the inkjet technique, one or more nozzles placed on a robot arm supply the polymer into each through-hole. The deposition of the polymer can be carried out for several through-holes simultaneously and notably for all of the through-holes situated on the same row of the substrate 1.

For the serigraphy, a flexible mask is used, in other words for example a very thin flexible metal foil of thickness typically around 100 μm and through which holes are pierced.

The arrangement of the holes corresponds to the arrangement of the holes that have been formed in the substrate in such a manner that the holes in the flexible mask are superposed onto the holes in the substrate.

A given rough quantity of polymer is subsequently disposed onto the periphery of the mask and then spread out with a suitable means, such as a spreader blade, over the whole surface of the substrate. This spreading causes the polymer to fill the through-holes.

With this technique, all the through-holes can be simultaneously filled with polymer.

Irrespective of the method used to fill the through-holes, the substrate could be placed on a vacuum table whose surface could undergo a prior treatment in order to obtain a partially or totally hydrophilic or hydrophobic coating.

The use of this vacuum table, potentially treated, prevents the polymer deposited in the through-hole from flowing under the substrate or else from becoming attached to the table after polymerization.

When the filling of the through-hole is partial, any swelling that may occur before or after hardening of the polymer should be avoided.

In practice, swelling can be avoided by making sure that the material forming the plug has a thermal expansion coefficient close to the substrate, by including a small amount of material whose thermal expansion coefficient is different from that of the substrate, or else by depositing the polymer on either side of the through-hole in order to balance the stresses.

FIG. 4a shows the optical module 12 prior to the formation of the lenses 5 and 6.

FIG. 4b illustrates a substrate 1, in which through-holes in the form of a truncated cone and being non-cylindrical have been formed. This particular shape of the through-holes allows, on the one hand, the filling of the through-hole to be facilitated and, on the other hand, the mechanical robustness of the plug obtained to be improved.

The improvement in the mechanical robustness is due to two reasons: on the one hand, since the hole in which the plug is to be inserted is conical, the plug is only then able to come out via one side; on the other hand, since the side walls of the hole are inclined, the contact surface area between the substrate and the plug is larger.

The gap between the plug and the side walls is preferably not filled for the reasons previously mentioned.

Generally speaking, the wetting angle of the polymer on the edge of the wall of the through-hole should be well controlled, which means that the holes must be formed with edges having a well-defined topology, in other words a truly circular shape.

If this is not the case, the materials composing the two lenses and also the plug should have an identical index and Abbe value.

The filling of the through-holes by the polymer material can lead to the creation of inclusions of air in the polymer plug obtained. This can affect the optical qualities of the optical module obtained.

For this reason, the filling process can be carried out under vacuum, so as to avoid these air inclusions.

In certain cases, the presence of air bubbles may be used in order to allow the polymer material to expand, in the case of a rise in temperature, without causing any stress on the substrate 2. In this case, the filling process will be implemented in such a manner as to trap these air bubbles within the roughness texture or irregularities coming from the etching of the substrate.

In practice, the characteristics of the polymer and the filling rate should be chosen judiciously.

Finally, the filling of the through-holes could be facilitated by the use of a chemical catalyst for the surface of the hole, allowing the wetability of the polymer on the substrate to be enhanced.

Once the plugs 20 have been formed, lenses 5, 6 can be formed at each end of a through-hole 2, where only a single lens may be formed in certain holes.

The method described with reference to FIG. 1 may of course be implemented.

FIG. 3 shows that, on either side of the lens 6, the plug 20 is flush with the surface of the substrate 1.

In this case, the method of filling must be implemented in such a manner that the polymer does not create beads on the outside face of the substrate, on the periphery of the through-hole.

Indeed, if the formation of the lens 6 requires the use of a mold, these beads could prevent the mold from coming into contact with the outside surface of the substrate 1. It would not then allow the desired shape for the lens 6 to be obtained.

In practice, the thickness of the polymer present on the surface of the substrate 1 will be at most of the order of a few hundred microns, when a mold must be used to form the lens 6.

In the embodiment illustrated in FIG. 3, the indices of the materials composing, on the one hand, the plug 20 and, on the other hand, the lenses 5 and 6, may be different. Moreover, the indices of these materials can have different Abbe values.

By way of example, the material of the lens 5 can have an index n1 of around 1.5 and an Abbe value c1 of around 60, whereas the second lens 6 will have an index n2 of around 1.7 and an Abbe value c2 of around 30.

Furthermore, the material composing the plug could have the same index and the same Abbe value as the lens 5 or the lens 6. This enables an achromatic doublet to be formed which allows the chromatic aberration to be corrected.

The material forming the plug could also have an index and an Abbe value different from those of the lenses 5 and 6 so as to optimize the image quality of the final imaging system.

This embodiment allows not only chromatic aberrations but also geometric aberrations to be reduced (a Cooke triplet for example). This embodiment can be advantageous when the optical module is designed for a high-resolution imaging system comprising a small number of optical modules.

Generally speaking, the thermal expansion coefficient of each of the materials is chosen so as to minimize the stresses on the substrate, in particular when the temperature rises. Thus, it will be chosen substantially equal to, or even slightly higher than, the thermal expansion coefficient of the substrate. It will be typically around 3.10⁻⁶/° C. when the substrate is a silicon substrate.

Lastly, other optical interfaces could be formed on the lenses 5 and 6, as has been explained with regard to FIG. 2.

It should be noted that, in all the embodiments, the invention allows two lenses per through-hole to be obtained for all or part of the holes in the substrate, which can correspond to four non-planar optical interfaces per hole.

Reference is now made to FIG. 5 which illustrates, along a dicing plan, an optical device according to the invention.

This optical device is composed of three optical means 71 to 73, which are separated from one another by means of spacers 70. Each of these optical means comprises a through-hole in which a lens (means 71) or two lenses (means 72, 73) have been formed.

A CMOS sensor 8 is associated with this stack of optical means, which sensor is also separated from the stack of optical means by a spacer 70.

Given that the substrates of the CMOS sensor and of the optical means are opaque, the optical device does not comprise any optical encasement around the stack.

Moreover, when the substrate of the optical means is made of silicon, like that of the CMOS sensor, the stack exhibits a good behavior when the temperature rises. Indeed, all the substrates are then deformed in an identical manner.

The reference 80 denotes a protection glass, the reference 81 an infrared filter and the reference 82 an optical encasement. The latter is needed to avoid infrared light and electromagnetic waves passing through the CMOS sensor and degrading the signal/noise ratio of the image.

This optical device is obtained by dicing a package according to the invention formed from a stack of optical modules according to the invention and from a substrate comprising a plurality of CMOS sensors 8. This stack is formed in the direction of the axis XX′ and the dicing planes of the package also run along this same axis XX′.

Each optical means is therefore a part of an optical module of the package.

FIG. 5 shows that the optical device comprises vias 9 for the electronic addressing.

In order to form these electrical vias, other through-holes are made in each of the substrates 1 of the optical modules, on the periphery of the substrates, during the formation of the through-holes 2. The same method can be implemented to form all of the through-holes.

When the substrate is made of silicon, all of the holes are formed by a technique of the DRIE type.

With a substrate made of plastic, the holes are obtained directly during the molding of the substrate.

The diameter of these other holes is for example around 100 μm.

These holes are subsequently filled with a conductive polymer, the filling being applied to each substrate.

This filling is preferably carried out under vacuum in order to avoid creating inclusions of air bubbles.

The polymer is subsequently hardened by heating or by UV polymerization.

By way of example, the polymer can be of the polyacetylene, polyaniline, polypyrrole or polythyophene type.

The reference numbers appearing in the claims are only intended to facilitate their understanding and in no way limit their scope.

1. An optical module formed from a substrate having a plurality of through-holes and from optical elements disposed in the holes within which, in at least one hole, two lenses are disposed, said lenses being made of at least one polymer material, being transparent in the range 400 nm-700 nm, each of the lenses being defined by an external optical interface and an internal optical interface, wherein a gap is arranged between the internal optical interfaces of the two lenses and in that the substrate is devoid of any polymer material between two adjacent through-holes.

2. The module as claimed in claim 1, wherein the external optical interface can have a spherical or aspherical shape.

3. The module as claimed in claim 1, wherein the internal optical interface has a plane, spherical or aspherical shape.

4. The module as claimed in claim 1, wherein the two lenses disposed within the same through-hole have different indices and Abbe values.

5. The module as claimed in claim 1, wherein the external optical interface of at least one of the two lenses disposed within the same through-hole is covered with another optical interface.

6. The module as claimed in claim 5, wherein this other optical interface is aspherical.

7. The module as claimed in claim 5, wherein this other optical interface is made of a material of index different from the material forming the lens.

8. The module as claimed in claim 1, wherein, in at least one through-hole comprising two lenses, the gap included between the two internal optical interfaces of the two lenses is filled with a material that is transparent in the range 400 nm-700 nm.

9. The module as claimed in claim 8, wherein the index and the Abbe value of this material situated between the two internal optical interfaces are different from those of at least one of the two lenses.

10. The module as claimed in claim 1, wherein the external optical interface of at least one of the two lenses disposed within the same through-hole is covered by an anti-reflective and/or anti-infrared coating.

11. A wafer-level package comprising at least one optical module as claimed in claim 1, and a substrate comprising a plurality of imaging systems.

12. The package as claimed in claim 11, wherein it also comprises spacers for separating the optical modules from one another or else the optical module(s) from the imaging system.

13. The package as claimed in claim 11, wherein said substrate of said at least one optical module is made of an opaque material.

14. The package as claimed in claim 11, wherein it comprises electrical vias for the electronic addressing passing through the substrates.

15. An optical device comprising a part of a wafer-level package as claimed in claim 11, diced along planes running in an axial direction.

16. A method for the formation of an optical module as claimed in claim 1, consisting in implementing the following steps:
(a) form a plurality of through-holes in a substrate,
(b) deposit, onto both sides of at least one through-hole, a drop of a thermally- or UV-hardening polymer, which is transparent in the range 400 nm-700 nm, a gap being arranged, within said hole, between the two drops of polymer, and that the substrate is devoid of any polymer between two adjacent through-holes, and
(c) harden said polymer by exposure to heat or to UV.

17. The method as claimed in claim 16, consisting, between the steps (b) and (c), in shaping said drop of polymer by molding.

18. The method as claimed in claim 16, comprising, after the step (c), a step (d) consisting in depositing on at least one of the two lenses formed within a through-hole, another drop of polymer that will coat the lens previously formed and a step (e) consisting in hardening said drop of polymer by exposure to heat or to UV.

19. The method as claimed in claim 18, in which this step (e) is followed by a step (f) for the shaping of this other drop of polymer by molding.

20. The method as claimed in claim 16, in which the indices and Abbe values of the various materials used to form the lenses and/or the additional optical interfaces are different.

21. The method as claimed in claim 16, in which, prior to the step (b), the method consists in filling said through-hole at least partially with a thermally- or UV-hardening material.

22. A method for fabricating a package as claimed in claim 11, consisting in forming several optical modules according to claim 16 and in stacking them along an axial direction, with a substrate comprising a plurality of imaging systems.

23. The method as claimed in claim 22, in which, during the step (a), additional holes are formed through all the substrates, these holes being aligned axially, the method consisting in filling these holes with a conductive polymer, then in hardening this polymer, in such a manner as to form electrical vias for the electronic addressing.

24. A method for fabricating an optical device, notably a camera device, consisting in implementing the method as claimed in claim 22 and a complementary step for cutting it up into die along planes running in an axial direction, so as to separate the package into individual optical devices.
